(19) United States
(12) Patent Application Publication
(10) Pub. No.: US 2023/0422419 A1
(43) Pub. Date: Dec. 28, 2023

(54) ELECTRONIC DEVICE INCLUDING HOUSING, AND METHOD FOR MANUFACTURING HOUSING

(71) Applicant: SAMSUNG ELECTRONICS CO., LTD., Suwon-si (KR)

(72) Inventors: Byungseon HWANG, Suwon-si (KR); Deokhee LEE, Suwon-si (KR); Sunggyu LEE, Suwon-si (KR)

(21) Appl. No.: 18/216,530

(22) Filed: Jun. 29, 2023

Related U.S. Application Data
(63) Continuation of application No. PCT/KR2022/003570, filed on Mar. 15, 2022.

(30) Foreign Application Priority Data
Mar. 23, 2021 (KR) 10-2021-0037040

(51) Int. Cl. H04M 1/02

(52) U.S. Cl. CPC H04M 1/0283

(57) ABSTRACT

An electronic device includes a housing forming the exterior of the electronic device, the housing comprising: a base material forming the shape of the housing; a first layer positioned on one surface of the base material and containing a color paint; and a second layer positioned on one surface of the first layer and containing a visible light-transmitting material, wherein the second layer contains an infrared absorbing material, and the second layer may include a marking region on a surface exposed to the outside of the housing.

### CROSS-REFERENCE TO RELATED APPLICATION(S

This application is a continuation application, claiming priority under § 365(c), of International Application No. PCT/KR2022/003570 filed on Mar. 15, 2022, which is based on and claims the benefit of Korean patent application number 10-2021-0037040 filed on Mar. 23, 2021, in the Korean Intellectual Property Office, the disclosures of which are incorporated by reference herein in their entireties.

### TECHNICAL FIELD

Various embodiments of the disclosure relate to an electronic device including a housing and a method for manufacturing the housing.

### BACKGROUND ART

In order to improve the aesthetic sense of an electronic device product and to emphasize the design differentiation thereof, various marking techniques are being applied to constituent elements of an appearance of the electronic device, for example, a housing. Among them, in case of using near infrared rays in performing laser marking of the housing of the electronic device in the related art, a problem may occur, in which the processing quality is not uniform depending on an ingredient or a physical property of a processed object.

### DISCLOSURE OF INVENTION

### Technical Problem

In performing laser marking of the housing of the electronic device, especially, in case that the surface of a processed object is transparent, near infrared rays having a wavelength near the wavelength of a visible light are absorbed in a color layer or an injection resin of a base material after penetrating a transparent layer, and here, the laser marking by heat is performed. In this case, since respective layers forming the housing have different ingredients and physical properties, several problems may occur on boundaries of the layers, and this may cause the product quality to deteriorate. Representative quality deterioration problems occurring when the related art is applied may be an invisible marking region or messy forming of the marking region even if being visible, non-distinctive contrast of colors (color difference or brightness difference), coatings of the respective layers being badly damaged, seceded, lost, or peeled off, the injection resin of the base material being damaged, and the like. Further, in the related art, since it is difficult to form a visible and elaborate glossy/matte area or protrusion on the transparent layer of the housing, or the marking is not well made in case of a bright color layer of the housing, it is not possible to implement various shapes of markings that can heighten the aesthetic sense.

The disclosure is to solve the above-described problems and to provide an electronic device having an improved appearance quality. Various embodiments of the disclosure may provide an electronic device including a housing that contains a near infrared absorption material and includes a marking area, and a method for manufacturing the housing.

### Solution to Problem

According to various embodiments, an electronic device may include: a housing forming an appearance of the electronic device, wherein the housing includes: a base material forming a shape of the housing; a first layer located on one surface of the base material and containing a color paint; and a second layer located on one surface of the first layer and containing a visible light permeable material, wherein the second layer contains a near infrared absorption material, and the second layer includes a marking area on a side of a surface (hereinafter, referred to as “front surface”) that is exposed to an outside of the housing.

According to an embodiment, the first layer may contain a near infrared absorption material, and the first layer may include a marking area.

According to various embodiments, an electronic device may include: a housing forming an appearance of the electronic device, wherein the housing includes: a base material forming a shape of the housing; a first layer located on one surface of the base material and containing a color paint; and a second layer located on one surface of the first layer and containing a visible light permeable material, wherein the first layer has a bright color with high brightness, the first layer contains a near infrared absorption material, and the first layer includes a marking area.

According to various embodiments, an electronic device may include: a housing forming an appearance of the electronic device, wherein the housing includes: a base material forming a shape of the housing; and a first layer located on one surface of the base material and containing a visible light permeable material, wherein the first layer contains a near infrared absorption material, and the first layer includes a marking area on a side of an opposite surface (hereinafter, referred to as “rear surface”) to a surface that is exposed to an outside of the housing.

According to an embodiment, the near infrared absorption material may have a high absorption rate at a wavelength of 1000 to 1100 nm.

According to an embodiment, the near infrared absorption material may be at least one kind selected from a group consisting of phthalocyanine-based compounds, diimmonium-based compounds, sulfonate-group containing hydrophilic cyanine-based dyes, indocyanine green (ICG), cyanine 5.5 (Cy 5.5), and cyanine 7 (Cy 7).

According to an embodiment, the marking area may be an etching area.

According to an embodiment, the etching area may be a matted area.

According to an embodiment, the marking area may be an embossing area.

According to an embodiment, the embossing area may include an area protruded toward the surface that is exposed to the outside of the housing.

According to an embodiment, the marking area may be a discoloration area.

According to an embodiment, the discoloration area may be an area in which a bright color is changed to a dark color.

According to an embodiment, the housing may be a protection cover for protecting at least a partial area of the electronic device.

According to various embodiments, a method for manufacturing a housing of an electronic device may include: preparing a base material; forming a first layer containing a color paint on one surface of the base material; forming a second layer containing a visible light permeable material on one surface of the first layer; and marking on the second layer with a near infrared laser at a wavelength of 1064 nm, wherein forming the second layer may include containing a near infrared absorption material in the second layer.

According to various embodiments, a method for manufacturing a housing of an electronic device may include: preparing a base material; forming a first layer containing a color paint on one surface of the base material; forming a second layer containing a visible light permeable material on one surface of the first layer; and marking on the first layer with a near infrared laser at a wavelength of 1064 nm, wherein forming the first layer may include containing a near infrared absorption material in the first layer.

According to various embodiments, a method for manufacturing a housing of an electronic device may include: preparing a base material; forming a first layer containing a visible light permeable material on one surface of the base material; and marking on the first layer with a near infrared laser at a wavelength of 1064 nm, wherein forming the first layer may include containing a near infrared absorption material in the first layer.

According to an embodiment, in the method for manufacturing a housing of an electronic device, the near infrared absorption material may be at least one kind selected from a group consisting of phthalocyanine-based compounds, diimmonium-based compounds, sulfonate-group containing hydrophilic cyanine-based dyes, indocyanine green (ICG), cyanine 5.5 (Cy 5.5), and cyanine 7 (Cy 7).

According to an embodiment, marking with the near infrared laser may be etching.

According to an embodiment, marking with the near infrared laser may be embossing.

According to an embodiment, marking with the near infrared laser may be discoloring.

### Advantageous Effects of Invention

According to various embodiments of the disclosure, since a transparent layer or a color layer of a housing contains a near infrared absorption material that selectively absorbs near infrared rays at a high rate, it is possible to provide a housing including a marking area having an improved appearance quality without deterioration of the quality in accordance with color or physical property differences of respective layers, an electronic device including the housing, and a method for manufacturing the housing.

Specifically, according to various embodiments of the disclosure, it is possible to provide an electronic device in which a visible and elaborate glossy/matted area is formed on a transparent layer of a housing. Further, it is possible to provide an electronic device in which visible protrusions are formed on a transparent layer of a housing. Further, it is possible to provide an electronic device in which a marking area having a distinctive contrast of a bright color and a dark color is formed on a color layer of a housing without any additional work.

In addition, various effects that are directly or indirectly grasped can be provided through this document.

### BRIEF DESCRIPTION OF DRAWINGS

In relation to the description of the drawings, the same or similar reference numerals may be used for the same or similar constituent elements.

FIG. 1A is a perspective view of a front surface of an electronic device according to various embodiments of the disclosure.

FIG. 1B is a perspective view of a rear surface of an electronic device according to various embodiments of the disclosure.

FIG. 2 is a cross-sectional view of a housing including at least one marking area on a surface (front surface) that is exposed to an outside of the housing according to various embodiments of the disclosure.

FIG. 3A is a cross-sectional view of a housing including at least one etching area on a front surface of the housing according to various embodiments of the disclosure.

FIG. 3B is a cross-sectional view of a housing including at least one etching area on a front surface of the housing according to various embodiments of the disclosure.

FIG. 4 is a cross-sectional view of a housing including at least one embossing area on a front surface of the housing according to various embodiments of the disclosure.

FIG. 5 is a cross-sectional view of a housing including at least one marking area on the housing according to various embodiments of the disclosure.

FIG. 6A is a cross-sectional view of a housing including at least one marking area on an opposite surface (rear surface) of a surface that is exposed to an outside of the housing according to various embodiments of the disclosure.

FIG. 6B is a cross-sectional view of a housing including at least one marking area on a rear surface of the housing according to various embodiments of the disclosure.

FIG. 7A depicts an actual surface of a housing on which a marking area is formed according to various embodiments of the disclosure.

FIG. 7B depicts an enlarged actual surface of a housing on which a marking area is formed according to various embodiments of the disclosure.

FIG. 7C depicts an actual cross-section of a housing on which a marking area is formed according to various embodiments of the disclosure.

FIG. 7D depicts an actual cross-section of a housing on which a marking area is formed by a method in the related art.

FIG. 8 is a process chart illustrating a method for manufacturing a housing according to various embodiments of the disclosure.

FIG. 9 is a process chart illustrating a method for manufacturing a housing according to various embodiments of the disclosure.

FIG. 10 is a process chart illustrating a method for manufacturing a housing according to various embodiments of the disclosure.

### MODE FOR THE INVENTION

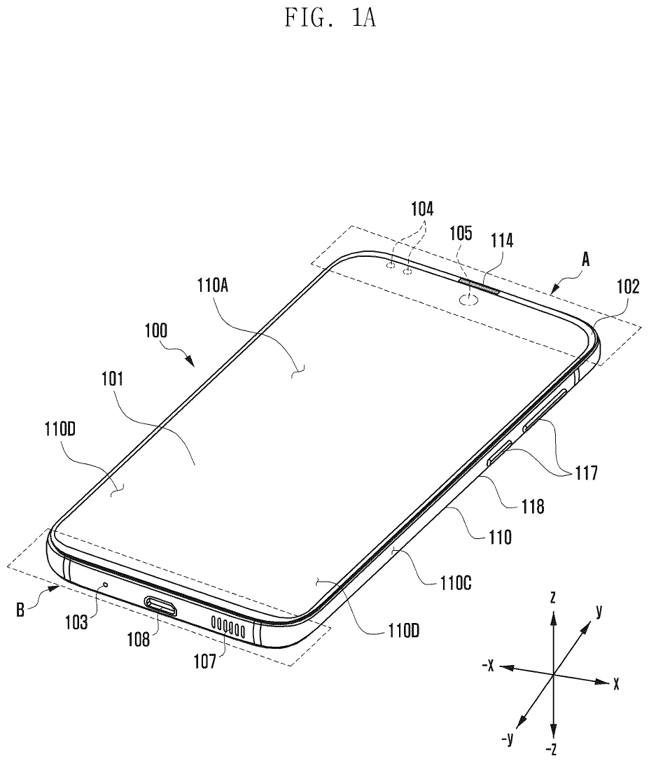

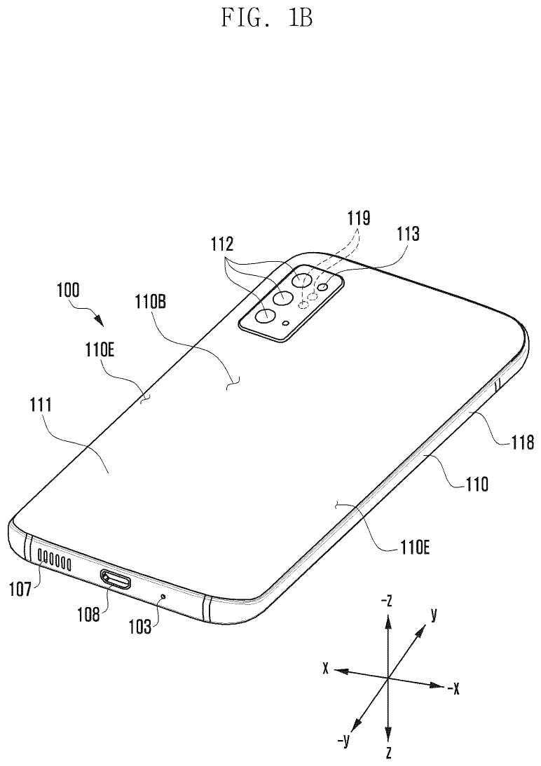

FIG. 1A is a perspective view showing a front surface of an electronic device according to various embodiments of the disclosure. FIG. 1B is a perspective view showing a rear surface of the electronic device shown in FIG. 1A according to various embodiments of the disclosure.

Referring to FIGS. 1A and 1B, an electronic device 100 may include a housing 110 that includes a first surface (or front surface) 110A, a second surface (or rear surface) 110B, and a lateral surface 110C that surrounds a space between the first surface 110A and the second surface 110B. The housing 110 may refer to a structure that forms a part of the first surface 110A, the second surface 110B, and the lateral surface 110C. The first surface 110A may be formed of a front plate 102 (e.g., a glass plate or polymer plate coated with a variety of coating layers) at least a part of which is substantially transparent. The second surface 110B may be formed of a rear plate 111 which is substantially opaque. The rear plate 111 may be formed of, for example, coated or colored glass, ceramic, polymer, metal (e.g., aluminum, stainless steel (STS), or magnesium), or any combination thereof. The lateral surface 110C may be formed of a lateral bezel structure (or “lateral member”) 118 which is combined with the front plate 102 and the rear plate 111 and includes a metal and/or polymer. The rear plate 111 and the lateral bezel structure 118 may be integrally formed and may be of the same material (e.g., a metallic material such as aluminum).

The front plate 102 may include two first regions 110D disposed at long edges thereof, respectively, and bent and extended seamlessly from the first surface 110A toward the rear plate 111. Similarly, the rear plate 111 may include two second regions 110E disposed at long edges thereof, respectively, and bent and extended seamlessly from the second surface 110B toward the front plate 102. The front plate 102 (or the rear plate 111) may include only one of the first regions 110D (or of the second regions 110E). The first regions 110D or the second regions 110E may be omitted in part. When viewed from a lateral side of the electronic device 100, the lateral bezel structure 118 may have a first thickness (or width) on a lateral side where the first region 110D or the second region 110E is not included, and may have a second thickness, being less than the first thickness, on another lateral side where the first region 110D or the second region 110E is included.

The electronic device 100 may include at least one of a display 101, audio modules 103, 107 and 114, sensor modules 104 and 119, camera modules 105, 112 and 113, a key input device 117, an indicator, and connector holes 108 and 109. The electronic device 100 may omit at least one (e.g., the key input device 117 or the indicator) of the above components, or may further include other components.

The display 101 may be exposed through a substantial portion of the front plate 102, for example. At least a part of the display 101 may be exposed through the front plate 102 that forms the first surface 110A and the first region 110D of the lateral surface 110C. The display 101 may be combined with, or adjacent to, a touch sensing circuit, a pressure sensor capable of measuring the touch strength (pressure), and/or a digitizer for detecting a stylus pen. At least a part of the sensor modules 104 and 119 and/or at least a part of the key input device 117 may be disposed in the first region 110D and/or the second region 110E.

The audio modules 103, 107 and 114 may correspond to a microphone hole 103 and speaker holes 107 and 114, respectively. The microphone hole 103 may contain a microphone disposed therein for acquiring external sounds and, in a case, contain a plurality of microphones to sense a sound direction. The speaker holes 107 and 114 may be classified into an external speaker hole 107 and a call receiver hole 114. The microphone hole 103 and the speaker holes 107 and 114 may be implemented as a single hole, or a speaker (e.g., a piezo speaker) may be provided without the speaker holes 107 and 114.

The sensor modules 104 and 119 may generate electrical signals or data corresponding to an internal operating state of the electronic device 100 or to an external environmental condition. The sensor modules 104 and 119 may include a first sensor module 104 (e.g., a proximity sensor) and/or a second sensor module (e.g., a fingerprint sensor) disposed on the first surface 110A of the housing 110, and/or a third sensor module 119 (e.g., a heart rate monitor (HRM) sensor) and/or a fourth sensor module (e.g., a fingerprint sensor) disposed on the second surface 110B of the housing 110. The fingerprint sensor may be disposed on the second surface 110B as well as the first surface 110A (e.g., the display 101) of the housing 110. The electronic device 100 may further include at least one of a gesture sensor, a gyro sensor, an air pressure sensor, a magnetic sensor, an acceleration sensor, a grip sensor, a color sensor, an infrared (IR) sensor, a biometric sensor, a temperature sensor, a humidity sensor, a proximity sensor, or an illuminance sensor.

The camera modules 105, 112 and 113 may include a first camera device (e.g., camera module 105) disposed on the first surface 110A of the electronic device 100, and a second camera device 112 and/or a flash 113 disposed on the second surface 110B. The camera module 105 or the camera module 112 may include one or more lenses, an image sensor, and/or an image signal processor. The flash 113 may include, for example, a light emitting diode or a xenon lamp. Two or more lenses (infrared cameras, wide angle and telephoto lenses) and image sensors may be disposed on one side of the electronic device 100.

The key input device 117 may be disposed on the lateral surface 110C of the housing 110. The electronic device 100 may not include some or all of the key input device 117 described above, and the key input device 117 which is not included may be implemented in another form such as a soft key on the display 101. The key input device 117 may include the sensor module disposed on the second surface 110B of the housing 110. In another embodiment, the key input device 117 may be implemented using a pressure sensor included in the display 101.

The indicator may be disposed on the first surface 110A of the housing 110. For example, the indicator may provide status information of the electronic device 100 in an optical form. The indicator may provide a light source associated with the operation of the camera module 105. The indicator may include, for example, a light emitting diode (LED), an infrared (IR) LED, or a xenon lamp.

The connector holes 108 and 109 may include a first connector hole 108 adapted for a connector (e.g., a universal serial bus (USB) connector or an interface connector port module) for transmitting and receiving power and/or data to and from an external electronic device. The connector hole 108 may include a second connector hole 109 (not shown) adapted for a connector (e.g., an earphone jack) for transmitting and receiving an audio signal to and from an external electronic device.

Some sensor modules of camera modules 105 and 112, some sensor modules of sensor modules 104 and 119, or an indicator may be arranged to be exposed through a display 101. For example, the camera module 105, the sensor module 104, or the indicator may be arranged in the internal space of an electronic device 100 so as to be brought into contact with an external environment through an opening of the display 101, which is perforated up to a front plate 102. In another embodiment, some sensor modules 104 may be arranged to perform their functions without being visually exposed through the front plate 102 in the internal space of the electronic device. For example, in this case, an area of the display 101 facing the sensor module may not require a perforated opening.

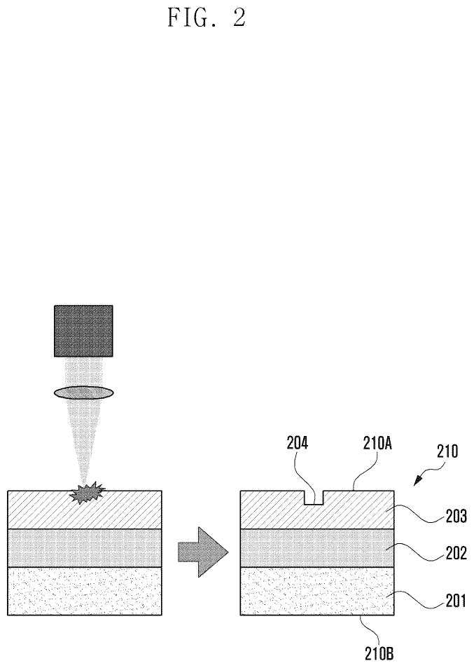

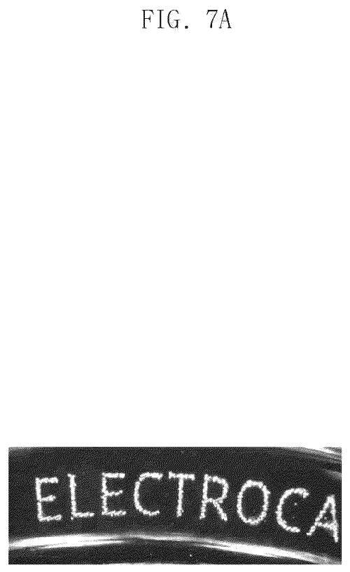

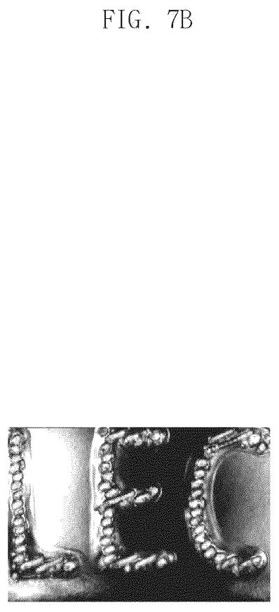

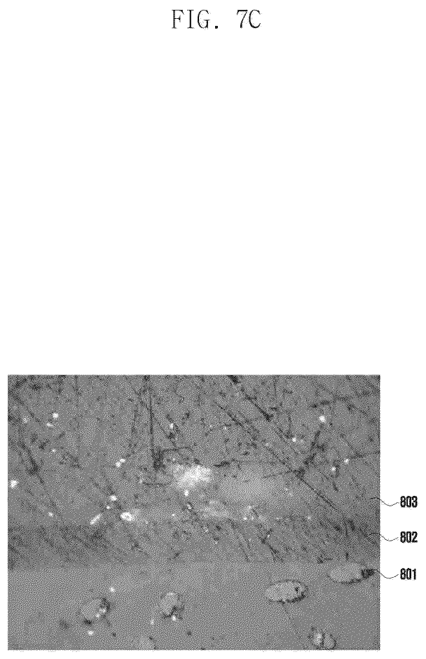

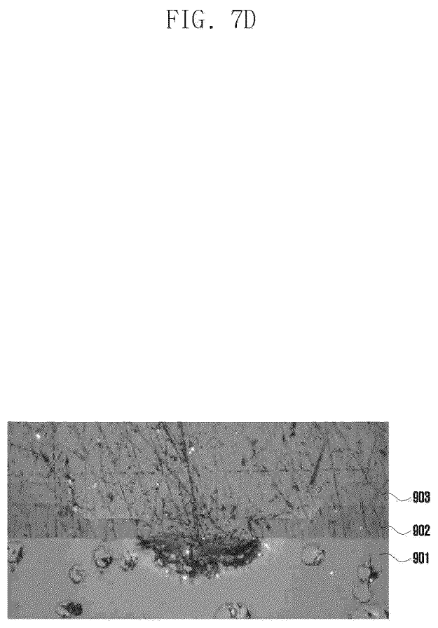

FIG. 2 is a cross-sectional view of a housing including at least one marking area on a surface (e.g., a front surface) that is exposed to an outside of the housing according to various embodiments of the disclosure. FIGS. 7A to 7C depict actual surfaces and cross-sections of housings on which marking areas are formed according to various embodiments of the disclosure.

With continued reference to FIG. 2, a first electronic device of the disclosure may include: a housing 210 forming an appearance of the first electronic device, wherein the housing includes: a base material 201 forming a shape of the housing; a first layer 202 located on one surface of the base material 201 and containing a color paint; and a second layer 203 located on one surface of the first layer 202 and containing a visible light permeable material, wherein the second layer 203 contains an infrared absorption material (e.g., a near infrared absorption material), and the second layer includes a marking area 204 on a side of a front surface 210a of the housing.

The marking area 204 may be formed in a manner that the second layer 203 contains the near infrared absorption material. Typically, in case of performing laser marking with near infrared rays having a wavelength near the wavelength of a visible light, for example, at a wavelength of 1064 nm, a layer (hereinafter, referred to as “transparent layer”) containing a visible light permeable material is permeated by the near infrared rays as they are, and thus the marking may become difficult. However, since the second layer of the housing according to the disclosure contains a near infrared absorption material, the second layer absorbs the near infrared rays although the second layer is the transparent layer, and thus various marking processes can be performed. As described above, since the marking process can be performed on the transparent layer, it is possible to reduce a poor marking quality problem that may typically occur on a boundary surface between the second layer and the first layer (hereinafter, referred to as “color layer”) containing a color paint or on a boundary surface between the first layer and an injection resin of the base material.

With reference to FIGS. 7A to 7C, it can be identified that the housing on which a marking area is formed according to various embodiments of the disclosure has a considerably improved marking quality.

FIG. 7A depicts an actual surface of a housing on which a marking area is formed according to various embodiments of the disclosure, which represents one of examples in which an elaborate text type marking area is formed on the second layer according to the disclosure. It can be viewed that the visibility of the marking region is very prominent and clear.

FIG. 7B depicts an enlarged actual surface of a housing on which a marking area is formed according to various embodiments of the disclosure, which represents an enlarged surface of the marking region. It can be viewed that elaborate and clear etching is made on the surface of the second layer.

FIG. 7C depicts an actual cross-section of a housing on which a marking area is formed according to various embodiments of the disclosure, which represents an enlarged cross-section of the housing. It can be viewed that only the surface of the second layer 803 is etched so as not to exert an influence on the first layer 802 and the injection resin 801 of the base material, and thus reliability of the marking material can be improved. In contrast, FIG. 7D is depicts an actual cross-section of a housing on which a marking area is formed by a method in the related art, and it can be viewed that a transparent layer 903 and a color layer 902 are lost and peeled off, and even an injection resin 901 of the base material is lost.

According to an embodiment of the disclosure, the infrared absorption material or near infrared absorption material may have a high absorption rate at a wavelength of 1000 to 1100 nm.

According to an embodiment of the disclosure, the infrared absorption material or near infrared absorption material may be at least one kind selected from a group consisting of phthalocyanine-based compounds, diimmonium-based compounds, sulfonate-group containing hydrophilic cyanine-based dyes, indocyanine green (ICG), cyanine 5.5 (Cy 5.5), and cyanine 7 (Cy 7). Through the above-described near infrared absorption materials or combinations thereof, the second layer having high visible light transmittance and high near infrared absorption rate can be formed.

According to an embodiment of the disclosure, the visible light permeable material contained in the second layer may be a polymer resin that is an ingredient giving gloss to the surface of the housing. The polymer resin may be a paint for coating that is an ingredient being used for a paint for spray coating, an ink for screen printing, an ink for pad printing, a coating liquid for roll coating, and a molding liquid for UV molding. Further, the polymer resin may be a thermosetting paint or a UV curable paint in accordance with a curing method. Further, the polymer resin may be ingredients used for a transparent topcoat paint of the outermost layer of the housing, a primer paint for securing adhesion between two layers, and a color paint for color implementation in accordance with the layers being applied. The polymer resin may be, for example, a urethane resin or an epoxy resin being used as the ingredients of a tinting film of a vehicle or a window pane.

According to an embodiment, the marking area 204 may be an etching area, an embossing area, or a discoloration area.

According to an embodiment, the marking area 204 may be included on the side of the front surface 210a of the housing 210 in the second layer 203, and preferably, at an upper end on the side of the front surface of the housing 210 in the second layer 203.

According to an embodiment of the disclosure, the marking area 204 may be included on the side of the front surface 210a of the housing 210 and in the second layer 203 in the first layer 202, and preferably, at the upper end on the side of the front surface 210a of the housing 210 and in the second layer 203 in the first layer 202.

According to an embodiment of the disclosure, the marking area 204 of FIG. 2 may be an etching area.

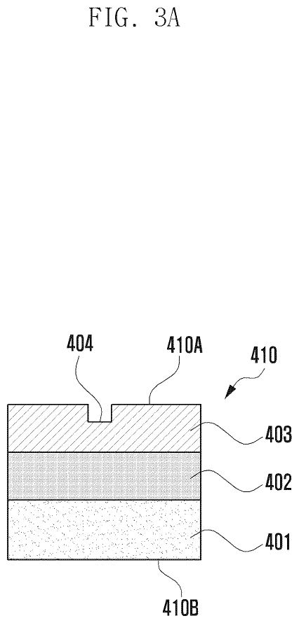

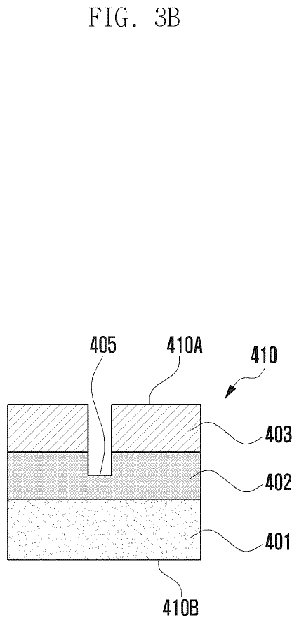

FIGS. 3A and 3B are cross-sectional views of a housing including at least one etching area on a front surface 210a of the housing 210 according to various embodiments of the disclosure.

With reference to FIG. 3A, according to an embodiment of the disclosure, a housing 410 forming an appearance of the electronic device may include: a base material 401 forming a shape of the housing; a first layer 402 located on one surface of the base material 401 and containing a color paint; and a second layer 403 located on one surface of the first layer 402 and containing a visible light permeable material, wherein the second layer 403 contains an infrared absorption material or a near infrared absorption material, and the second layer includes an etching area 404 on the side of a front surface 410A of the housing.

According to a non-limiting embodiment of the disclosure where the second layer 403 contains the near infrared absorption material, and the first layer 402 and the base material 401 do not contain the infrared absorption material or the near infrared absorption material, the transparent layer is imprinted, and the influence of the near infrared rays is minimized on the color layer and the base material 401 under the transparent layer, so that the damage of the color layer and the base material 401 can be reduced, and the marking quality can be further improved.

With reference to FIG. 3B, according to an embodiment of the disclosure, a housing 410 forming an appearance of the electronic device may include: a base material 401 forming a shape of the housing 410; a first layer 402 located on one surface of the base material 401 and containing a color paint; and a second layer 403 located on one surface of the first layer 402 and containing a visible light permeable material, wherein the first layer 402 and the second layer 403 contain infrared absorption materials or near infrared absorption materials, and the first layer 402 and the second layer 403 include an etching area 405 on the side of a front surface 410A of the housing 410.

According to an embodiment of the disclosure, in case that the first layer 402 and the second layer 403 contain the near infrared absorption material, the transparent layer and the color layer may be etched at the same time.

According to an embodiment of the disclosure, the etching area 404 of FIG. 3A or 405 of FIG. 3B may be a matte area. The region etched by the etching may have a relatively lower glossiness than the glossiness of the non-etched region.

According to an embodiment of the disclosure, the marking area 204 of FIG. 2 may be an embossing area.

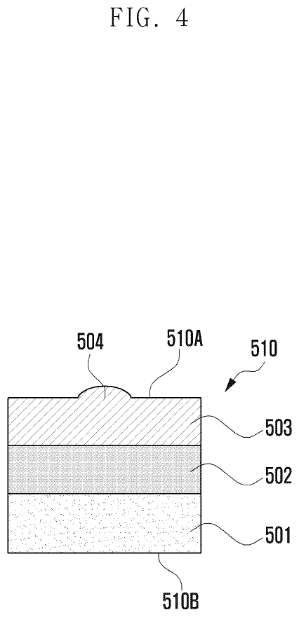

FIG. 4 is a cross-sectional view of a housing including at least one embossing area on a front surface of the housing according to various embodiments of the disclosure.

With reference to FIG. 4, according to an embodiment of the disclosure, a housing 510 forming an appearance of the electronic device may include: a base material 501 forming a shape of the housing 510; a first layer 502 located on one surface of the base material 501 and containing a color paint; and a second layer 503 located on one surface of the first layer 502 and containing a visible light permeable material, wherein the second layer 503 contains an infrared absorption material or a near infrared absorption material, and the second layer 503 includes an embossing area 504 on a side of a front surface 510A of the housing 510.

According to an embodiment of the disclosure, the embossing area 504 may include an area protruded toward the front surface 510A of the housing. In the related art, it is difficult to form a visible protrusion region on the transparent layer of the housing. However, according to one or more non-limiting embodiments of the present disclosure, it is possible to provide an electronic device in which a visible protrusion region is formed on the transparent layer of the housing. Further, the embodiment of the disclosure may be useful in case of intending to heighten the visibility by forming the protrusion region on the surface while lessening the color change of the housing.

According to an embodiment of the disclosure, the marking area 204 of FIG. 2 may be a discoloration area.

According to an embodiment of the disclosure, the discoloration area may be an area in which a bright color is changed to a dark color.

According to an embodiment of the disclosure, the housing 110 of FIGS. 1A and 1B and 210 of FIG. 2 may be a protection cover for protecting at least a partial area of the first electronic device 100.

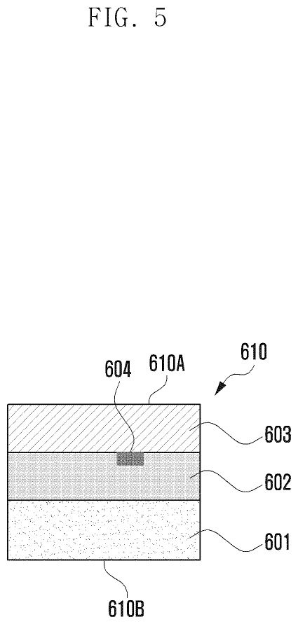

FIG. 5 is a cross-sectional view of a housing including at least one marking area on the housing according to various embodiments of the disclosure.

With reference to FIG. 5, a second electronic device according to various embodiments may include: a housing 610 forming an appearance of the second electronic device, wherein the housing 610 includes: a base material 601 forming a shape of the housing 610; a first layer 602 located on one surface of the base material 601 and containing a color paint; and a second layer 603 located on one surface of the first layer 602 and containing a visible light permeable material, wherein the first layer 602 has a bright color with high brightness, the first layer 602 contains an infrared absorption material or a near infrared absorption material, and the first layer 602 includes a marking area 604.

According to an embodiment of the disclosure, the marking area 604 may be a discoloration area.

According to an embodiment of the disclosure, the discoloration area may be an area in which a bright color is changed to a dark color.

Generally, if the color layer of the housing has a bright color, there is a strong tendency that the near infrared rays are not absorbed, but are reflected, and thus the marking may not be performed well by the related art. However, according to one or more non-limiting embodiments of the present disclosure, since the first layer 602, which is a color layer of a bright color, contains the near infrared absorption material, it is possible to provide an electronic device in which a marking area having a distinctive contrast of a bright color and a dark color is formed on the bright color layer of the housing 610 without any separate work, for example, addition of paints of other colors or addition of other processes.

According to an embodiment of the disclosure, the color paint may be a paint including at least one kind of a general organic or inorganic series color pigment, a metal series pigment, and an artificial pearl pigment in accordance with the target color. In particular, as a bright color paint, a paint including a white pigment, such as TiO₂ and ZnO, or at least one kind of the white pigment and a pigment being used for the above-described color paint may be used.

According to an embodiment of the disclosure, the infrared absorption material or the near infrared absorption material may be the same as that described in the first electronic device.

According to an embodiment of the disclosure, the visible light permeable material may be the same as that described in the first electronic device.

According to an embodiment of the disclosure, the housing 110 of FIGS. 1A and 1B and 610 of FIG. 5 may be a protection cover for protecting at least a partial area of the second electronic device 100.

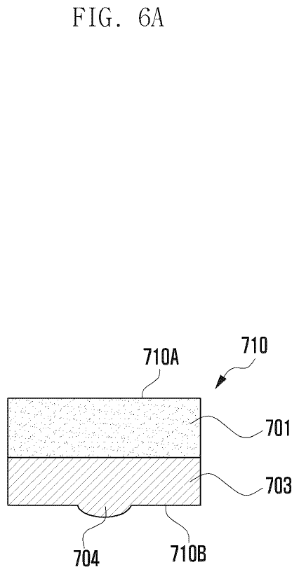

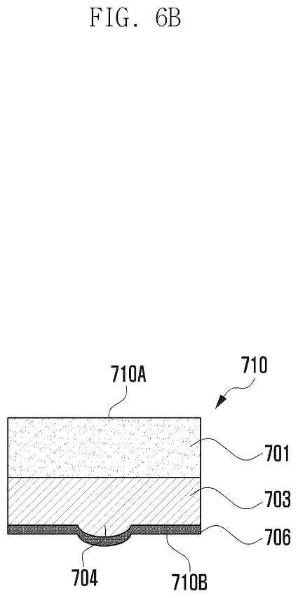

FIGS. 6A and 6B are cross-sectional views of a housing including at least one marking area on an opposite surface (rear surface) of a surface that is exposed to an outside of the housing according to various embodiments of the disclosure.

With reference to FIG. 6A, a third electronic device according to various embodiments may include: a housing 710 forming an appearance of the third electronic device, wherein the housing 710 includes: a base material 701 forming a shape of the housing; and a first layer 703 located on one surface of the base material 701 and containing a visible light permeable material, wherein the first layer 702 contains an infrared absorption material or a near infrared absorption material, and the first layer 702 includes a marking area 704 at a lower end of a side of a rear surface 710B of the housing 710.

According to an embodiment of the disclosure, the marking area 704 may be an etching area, an embossing area, or a discoloration area.

According to an embodiment, the marking area 704 may be included on the side of the rear surface of the housing 710 in the first layer 703, and preferably, at a lower end on the side of the rear surface of the housing 710 in the first layer 703.

According to an embodiment of the disclosure, the marking area 704 may be an embossing area.

With reference to FIG. 6A, according to an embodiment, the embossing area may include an area protruded toward the rear surface 710B of the housing 710. In the related art, it is difficult to form a visible protrusion region on the transparent layer of the housing. However, according to one or more non-limiting embodiments of the present disclosure, it is possible to provide an electronic device in which a visible protrusion region is formed on the transparent layer of the housing 710. Further, the embodiment of the disclosure may be useful in case of intending to heighten the visibility by forming the protrusion region on the surface while lessening the color change of the housing 710.

According to an embodiment of the disclosure, the marking area 704 may be an etching area.

According to an embodiment of the disclosure, the marking area 704 may be a discoloration area.

With reference to FIG. 6B, according to an embodiment, the housing 710 may include an additional coating layer 706 located on one surface of the first layer 703.

The additional coating layer 706 may be formed on the surface of the embossing area of the first layer 703, and may serve to secure the marking visibility. On the additional coating layer, a color coating layer (deposition, silver color, mirror color, or pearl color) having a high reflectivity may be applied, and in this case, the marking visibility for the embossing area can be maximized.

According to an embodiment of the disclosure, the infrared absorption material or the near infrared absorption material may be the same as that described in the first electronic device.

According to an embodiment of the disclosure, the visible light permeable material may be the same as that described in the first electronic device.

According to an embodiment of the disclosure, the housing 110 of FIGS. 1A and 1B and 710 of FIG. 6 may be a protection cover for protecting at least a partial area of the third electronic device 100.

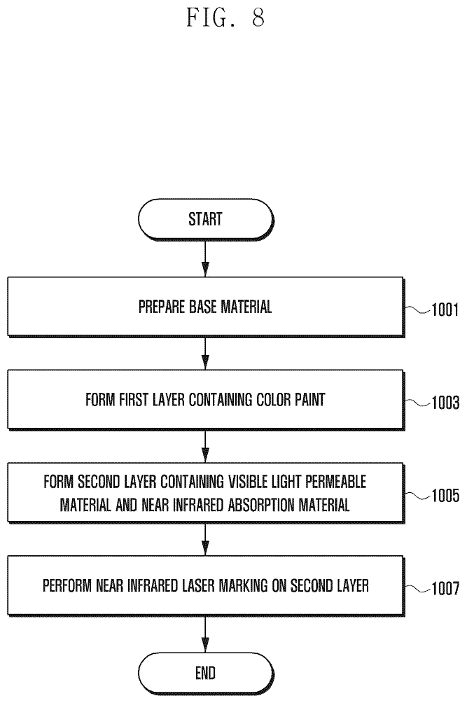

FIG. 8 is a process chart illustrating a method for manufacturing a housing according to various embodiments of the disclosure.

With reference to FIG. 8, according to various embodiments, a method for manufacturing a housing of an electronic device may include: preparing a base material (1001); forming a first layer containing a color paint on one surface of the base material (1003); forming a second layer containing a visible light permeable material on one surface of the first layer (1005); and marking on the second layer with a near infrared laser at a wavelength of 1064 nm (1007), wherein forming the second layer may include containing a near infrared absorption material in the second layer.

According to a non-limiting embodiment of the disclosure, in the method for manufacturing a housing of an electronic device, the near infrared absorption material may be at least one kind selected from a group consisting of phthalocyanine-based compounds, diimmonium-based compounds, sulfonate-group containing hydrophilic cyanine-based dyes, indocyanine green (ICG), cyanine 5.5 (Cy 5.5), and cyanine 7 (Cy 7).

According to a non-limiting embodiment of the disclosure, the visible light permeable material contained in the second layer may be a polymer resin that is an ingredient giving gloss to the surface of the housing. The polymer resin may be a paint for coating that is an ingredient being used for a paint for spray coating, an ink for screen printing, an ink for pad printing, a coating liquid for roll coating, and a molding liquid for UV molding. Further, the polymer resin may be a thermosetting paint or a UV curable paint in accordance with a curing method. Further, the polymer resin may be ingredients used for a transparent topcoat paint of the outermost layer of the housing, a primer paint for securing adhesion between two layers, and a color paint for color implementation in accordance with the layers being applied. The polymer resin may be, for example, a urethane resin or an epoxy resin being used as the ingredients of a tinting film of a vehicle or a window pane.

According to a non-limiting embodiment of the disclosure, the marking with the near infrared laser at the wavelength of 1064 nm (1007) may be etching, embossing, or discoloring by controlling a thermal action through adjustment of a power, a frequency, and a radiation time of laser.

According to an embodiment of the disclosure, the marking with the near infrared laser (1007) may be etching.

In controlling the thermal action of the near infrared laser, the etching may be performed in a manner that reactions, such as vaporization, explosion, evaporation, gassing, and gas expansion, occur actively as the heat generation becomes fast to raise the temperature, and as a result, the material of the laser radiation area disappears or breaks away to etch the desired region.

According to an embodiment of the disclosure, the marking with the near infrared laser (1007) may be embossing.

In controlling the thermal action of the near infrared laser, the embossing may be performed in a manner that as the heat generation becomes slow to lower the temperature, plastic deformation occurs due to re-solidification after instantaneous melting, micro-bubble generation, and expansion of the material to induce swelling of the desired region. In particular, the embossing may be useful in case of intending to increase the visibility through the swelling of the surface with a small change of the color.

According to an embodiment of the disclosure, the marking with the near infrared laser (1007) may be discoloring. According to an embodiment of the disclosure, the discoloring may be changing a bright color to a dark color.

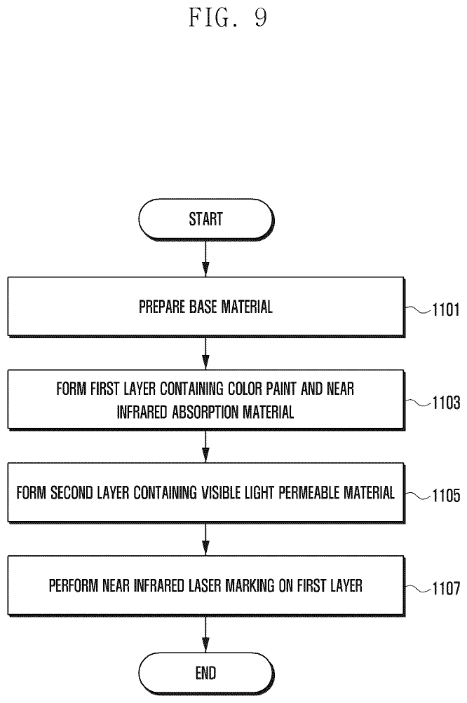

FIG. 9 is a process chart illustrating a method for manufacturing a housing according to various embodiments of the disclosure.

With reference to FIG. 9, according to various non-limiting embodiments, a method for manufacturing a housing of an electronic device may include: preparing a base material (1101); forming a first layer containing a color paint on one surface of the base material (1103); forming a second layer containing a visible light permeable material on one surface of the first layer (1105); and marking on the first layer with a near infrared laser at a wavelength of 1064 nm (1107), wherein forming the first layer may include containing a near infrared absorption material in the first layer.

According to a non-limiting embodiment of the disclosure, the marking with the near infrared laser (1107) may be discoloring.

The discoloring may be inducing high-temperature heat generation instantaneously by mixing the near infrared absorption material on a layer that requires discoloring since a polymer material generally has the characteristic of discoloring, such as yellowing, browning, blackening, or whitening, at high temperature. In case of inducing the discoloring of an embedded layer rather than a layer exposed to the surface, it is required to properly adjust energy with an output of a typically low level as compared with the case of etching. In the discoloring, careful consideration is required in selecting the output of the laser since if the energy is high as in the etching in the method for manufacturing the first electronic device, bubbles may be generated due to an excessive gas generation, or cosmetic defects may be caused due to separation between a discoloring induction layer and an adjacent layer.

According to a non-limiting embodiment of the disclosure, the discoloring may be changing a bright color to a dark color. In particular, the discoloring may be useful in case that the near infrared laser beam is also reflected when the color layer has a bright color (i.e., visible light reflectivity is high), and thus the marking is difficult.

According to an embodiment of the disclosure, the color paint may be a paint including at least one kind of a general organic or inorganic series color pigment, a metal series pigment, and an artificial pearl pigment in accordance with the target color. In particular, as a bright color paint, a paint including a white pigment, such as TiO₂ and ZnO, or at least one kind of the white pigment and a pigment being used for the above-described color paint may be used.

According to a non-limiting embodiment of the disclosure, the near infrared absorption material may be the same as that described in the method for manufacturing the first electronic device.

According to an embodiment of the disclosure, the visible light permeable material may be the same as that described in the method for manufacturing the first electronic device.

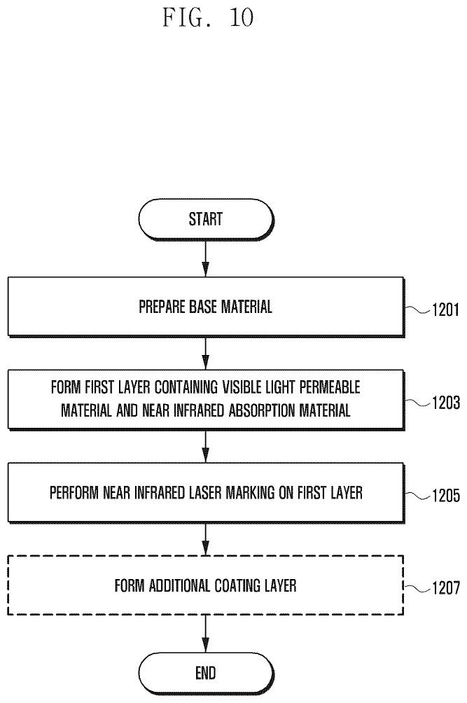

FIG. 10 is a process chart illustrating a method for manufacturing a housing according to various embodiments of the disclosure.

With reference to FIG. 10, according to various non-limiting embodiments, a method for manufacturing a housing of an electronic device may include: preparing a base material (1201); forming a first layer containing a visible light permeable material on one surface of the base material (1203); and marking on the first layer with a near infrared laser at a wavelength of 1064 nm (1205), wherein forming the first layer may include containing a near infrared absorption material in the first layer.

According to a non-limiting embodiment of the disclosure, the marking with the near infrared laser at the wavelength of 1064 nm (1205) may be etching, embossing, or discoloring by controlling a thermal action through adjustment of a power, a frequency, and a radiation time of the laser.

According to a non-limiting embodiment of the disclosure, the marking with the near infrared laser (1205) may be embossing.

In controlling the thermal action of the near infrared laser, the embossing may be performed in a manner that as the heat generation becomes slow to lower the temperature, plastic deformation occurs due to re-solidification after instantaneous melting, micro-bubble generation, and expansion of the material to induce swelling of the desired region. The embossing may be useful in case of intending to increase the visibility through the swelling of the surface with a small change of the color.

According to a non-limiting embodiment of the disclosure, the manufacturing method may further include forming an additional coating layer on one surface of the first layer (1207).

The forming the additional coating layer (1207) may be used for the purpose of securing the marking visibility through the swelling by implementing the additional color coating layer on the swelled surface after the swelling by the laser is implemented through coating up to the transparent layer of the rear surface of the housing. In particular, in case of applying a color coating layer (deposition, silver color, mirror color, or pearl color) having a high reflectivity, the marking visibility by the swelling can be maximized.

According to a non-limiting embodiment of the disclosure, the marking with the near infrared laser (1205) may be etching.

According to a non-limiting embodiment, the marking with the near infrared laser (1205) may be discoloring. According to an embodiment, the discoloring may be changing a bright color to a dark color.

According to a non-limiting embodiment of the disclosure, the near infrared absorption material may be the same as that described in the method for manufacturing the first electronic device.

According to a non-limiting embodiment of the disclosure, the visible light permeable material may be the same as that described in the method for manufacturing the first electronic device.

The electronic device according to various embodiments disclosed in this document may be various types of devices. The electronic device may include, for example, a portable communication device (e.g., smartphone), a computer device, a portable multimedia device, a portable medical device, a camera, a wearable device, or a home appliance. The electronic devices according to embodiments of the disclosure are not limited to the above-described devices.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. A singular form of a noun corresponding to an item may include one or a plurality of items unless the relevant context clearly indicates otherwise. In this document, each of such phrases as “A or B,” “at least one of A and B,” “at least one of A or B,” “A, B, or C,” “at least one of A, B, and C.” and “at least one of A, B, or C,” may include any one of, or all possible combinations of the items enumerated together in a corresponding one of the phrases. Such terms as “1st” and “2nd,” or “first” and “second” may be used to simply distinguish a corresponding component from another, and does not limit the components in other aspects (e.g., importance or order).

Embodiments of the disclosure that are disclosed in the specification and drawings are merely for easy explanation of the technical contents of the embodiments of the disclosure and proposal of specific examples to help understanding of the disclosure, but are not intended to limit the scope of the disclosure. Accordingly, it should be construed that all changes or modifications derived based on the technical concept of the various embodiments of the disclosure are included in the scope of the various embodiments of the disclosure in addition to the embodiments disclosed herein.

1. An electronic device comprising:
a housing forming an appearance of the electronic device,
wherein the housing includes:
a base material forming a shape of the housing;
a first layer located on a surface of the base material and containing a color paint, and
a second layer located on a surface of the first layer and containing a visible light permeable material,
wherein the second layer contains an infrared absorption material, and the second layer includes a marking area on a side of a surface that is exposed to an outside of the housing.

2. An electronic device comprising:
a housing forming an appearance of the electronic device,
wherein the housing includes:
a base material forming a shape of the housing;
a first layer located on a surface of the base material and containing a color paint; and
a second layer located on a surface of the first layer and containing a visible light permeable material,
wherein the first layer has a bright color with high brightness, the first layer contains an infrared absorption material, and the first layer includes a marking area.

3. An electronic device comprising:
a housing forming an appearance of the electronic device,
wherein the housing includes:
a base material forming a shape of the housing; and
a first layer located on a surface of the base material and containing a visible light permeable material,
wherein the first layer contains an infrared absorption material, and the first layer includes a marking area on a side of an opposite surface to a surface that is exposed to an outside of the housing.

4. The electronic device of claim 1, wherein the infrared absorption material has a high absorption rate at a wavelength of 1000 to 1100 nm.

5. The electronic device of claim 1, wherein the infrared absorption material is at least one kind selected from a group consisting of phthalocyanine-based compounds, diimmonium-based compounds, sulfonate-group containing hydrophilic cyanine-based dyes, indocyanine green (ICG), cyanine 5.5 (Cy 5.5), and cyanine 7 (Cy 7).

6. The electronic device of claim 1, wherein the marking area is an etching area.

7. The electronic device of claim 6, wherein the etching area is a matte area.

8. The electronic device of claim 1, wherein the marking area is an embossing area.

9. The electronic device of claim 8, wherein the embossing area comprises an area protruded toward the surface that is exposed to the outside of the housing.

10. The electronic device of claim 1, wherein the marking area is a discoloration area.

11. The electronic device of claim 1, wherein the first layer contains an infrared absorption material, and the first layer comprises a marking area.

12. The electronic device of claim 1, wherein the housing is a protection cover for protecting at least a partial area of the electronic device.

13. A method for manufacturing a housing of an electronic device comprising:
preparing a base material;
forming a first layer containing a color paint on a surface of the base material;
forming a second layer containing a visible light permeable material on a surface of the first layer; and
marking on the second layer with an infrared laser at a wavelength of 1064 nm,
wherein forming the second layer includes containing an infrared absorption material in the second layer.

14. A method for manufacturing a housing of an electronic device comprising:
preparing a base material;
forming a first layer containing a color paint on a surface of the base material;
forming a second layer containing a visible light permeable material on a surface of the first layer; and
marking on the first layer with an infrared laser at a wavelength of 1064 nm,
wherein forming the first layer includes containing an infrared absorption material in the first layer.

15. A method for manufacturing a housing of an electronic device comprising:
preparing a base material;
forming a first layer containing a visible light permeable material on a surface of the base material; and
marking on the first layer with an infrared laser at a wavelength of 1064 nm,
wherein forming the first layer includes containing an infrared absorption material in the first layer.
